(19) United States
(12) Patent Application Publication
(10) Pub. No.: US 2024/0327700 A1
(43) Pub. Date: Oct. 3, 2024

(54) CURABLE COMPOSITION, CURED LAYER USING THE SAME AND DISPLAY DEVICE INCLUDING THE CURED LAYER

(71) Applicant: SAMSUNG SDI CO., LTD., Yongin-si (KR)

(72) Inventors: Kyunghee KANG, Suwon-si (KR); Chul-Kyu KIM, Suwon-si (KR); Yonghee KANG, Suwon-si (KR); Jihyeon YIM, Suwon-si (KR); Sohyun KIM, Suwon-si (KR); Hyunjoo HAN, Suwon-si (KR); Bumjin LEE, Suwon-si (KR)

(21) Appl. No.: 18/605,678

(22) Filed: Mar. 14, 2024

(30) Foreign Application Priority Data
Mar. 29, 2023 (KR) 10-2023-0041367

(51) Int. Cl. C09K 11/02; G02B 5/20

(52) U.S. Cl. CPC C09K 11/025; G02B 5/206

(57) ABSTRACT

A curable composition includes (A) quantum dots; (B) a polymerizable compound; and (C) two or more light scatterers different from each other, wherein the light scatterers include a nano-sol. A cured layer produced by utilizing the curable composition and a display device including the cured layer are also provided.

### CROSS-REFERENCE TO RELATED APPLICATION

This application claims priority to and the benefit of Korean Patent Application No. 10-2023-0041367, filed on Mar. 29, 2023, in the Korean Intellectual Property Office, the entire content of which is incorporated herein by reference.

### BACKGROUND

### 1. Field

One or more embodiments of the present disclosure relate to a curable composition, a cured layer utilizing the curable composition, and a display device including the cured layer.

### 2. Description of the Related Art

In general, quantum dots may include surface characteristics (e.g., hydrophobicity), which limit or prevent dispersion of the quantum dots throughout a solvent. For example, it is difficult to introduce quantum dots into a polar system including other components such as a binder or a curable monomer.

For example, even in the case of a quantum dot ink composition being actively researched, a polarity of the composition is relatively low in an initial step (process) and quantum dots may be dispersed in a solvent utilized in a curable composition having a high hydrophobicity. Because it is difficult to achieve a content of 20 wt % or more, of the quantum dots based on a total amount of the composition, it may be impossible to increase light efficiency of the ink over a certain level. Even though the quantum dots are additionally added and dispersed in order to increase light efficiency, the resultant viscosity may then exceed a range (e.g., about 12 cPs) capable of, or suitable for, ink-jetting and thus proper processability may not be satisfied or achieved.

In order to achieve a viscosity range capable of, or suitable for, ink-jetting, an ink solid content (e.g., amount) may be lowered by dissolving (e.g., including) a solvent in quantities of 50 wt % (or more), based on a total amount of the composition. The additional solvent may also provide a somewhat satisfactory result in terms of viscosity, but nozzle drying due to solvent volatilization, nozzle clogging, and/or a thickness reduction of single film (e.g., over time after ink-jetting) may become worse. Therefore, in applications to actual processes, it is difficult to control a thickness deviation after curing, and it is difficult to control the viscosity range of the quantum dot ink composition by adding additional solvent.

Accordingly, a solvent-free quantum dot ink composition that does not include a solvent may be the most desirable form to be applied to an actual process. The current technique of applying a quantum dot itself to a solvent type or kind of composition is now limited to a certain extent.

As reported so far, in the case of the most desirable solvent type or kind composition to be applied to the actual process, the quantum dot, which is not surface-modified, such as ligand-substitution, has a content (e.g., amount) of about 20 wt % to 25 wt % based on a total amount of a solvent type or kind composition. Therefore, it is difficult to increase light efficiency and an absorption rate due to a limitation of viscosity. Meanwhile, attempts have been made to lower the content (e.g., amount) of the quantum dot(s) and increase the content (e.g., amount) of light scatterers in other improvement approaches, but these have also failed to solve a precipitation problem and a low light efficiency problem.

Accordingly, there is a growing need and/or desire for a solvent-free composition. In the case of a solvent-free composition, there are needs and/or requirements for reliability improvement, such as luminance, for example addressing a problem that a pattern may be detached due to a decrease of a close contacting force between a curing process or the subsequent process due to a high shrinkage during curing.

### SUMMARY

One or more embodiments of the present disclosure provide a curable composition having an excellent or suitable luminance improvement effect.

One or more embodiments of the present disclosure provide a cured layer produced utilizing the curable composition.

One or more embodiments of the present disclosure provide a display device including the cured layer.

According to one or more embodiments, a curable composition includes (A) quantum dots; (B) a polymerizable compound; and (C) two or more light scatterers different from each other, wherein the light scatterers include a nano-sol.

The nano-sol may have solution transmittance of greater than or equal to about 60% (e.g., in a visible wavelength region).

The nano-sol may include an organic-inorganic hybrid sol.

The organic-inorganic hybrid sol may include inorganic particles including titanium, zirconium, silicon, aluminum, tin, cerium, magnesium, zinc, or a combination thereof.

The inorganic particles may be included in an amount of about 50 wt % to about 80 wt % based on a total amount of the organic-inorganic hybrid sol.

The inorganic particles may have an average particle diameter of less than or equal to about 20 nm based on D50.

In one or more embodiments, the light scatterers may further include barium sulfate, calcium carbonate, titanium dioxide, zirconia, or a combination thereof.

The nano-sol may be included in a weight equal to or greater than that of the barium sulfate, calcium carbonate, titanium dioxide, zirconia, or a combination thereof.

In some embodiments, the nano-sol may be included in a weight of about 1 to about 5 times the weight of the barium sulfate, calcium carbonate, titanium dioxide, zirconia, or a combination thereof.

The polymerizable compound may include a compound represented by Chemical Formula 1.

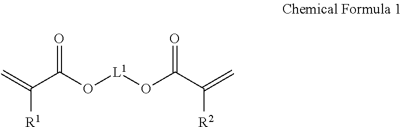

In Chemical Formula 1,
R¹ and R² may each independently be hydrogen or a methyl group, and
L¹ may be a substituted or unsubstituted C1 to C30 alkylene group or *-L^{a}-O-L^{b}-* (wherein L^{a} and L^{b} may each independently be a substituted or unsubstituted C1 to C20 alkylene group).

In one or more embodiments, the compound represented by Chemical Formula 1 may be represented by any one of Chemical Formulas 1-1 to 1-3.

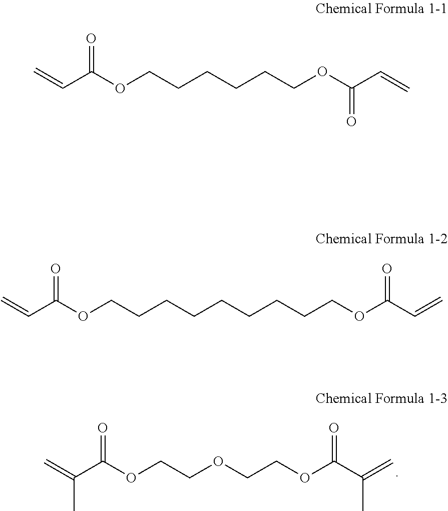

The quantum dots may be surface-modified quantum dots with (e.g., quantum dots surface-bonded with or including) any one of compounds represented by Chemical Formulas 2 to 15 or a combination thereof.

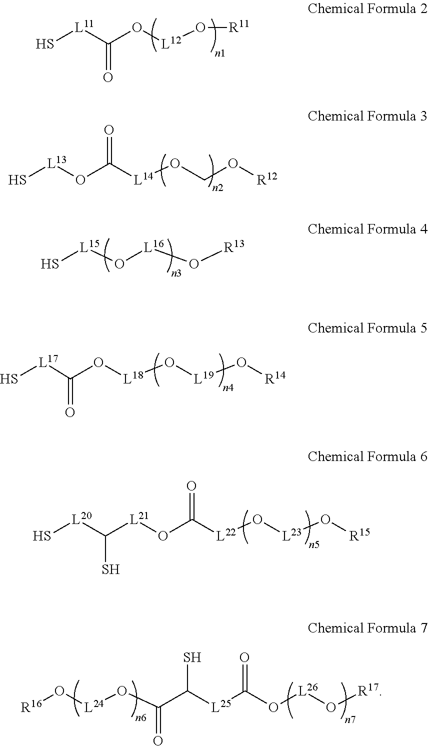

In Chemical Formulas 2 to 7,
R¹¹ to R¹⁷ may each independently be a substituted or unsubstituted C1 to C10 alkyl group or a substituted or unsubstituted C6 to C20 aryl group,
L¹¹ to L²⁶ may each independently be a substituted or unsubstituted C1 to C10 alkylene group, and
n1 to n7 may each independently be an integer of 0 to 10.

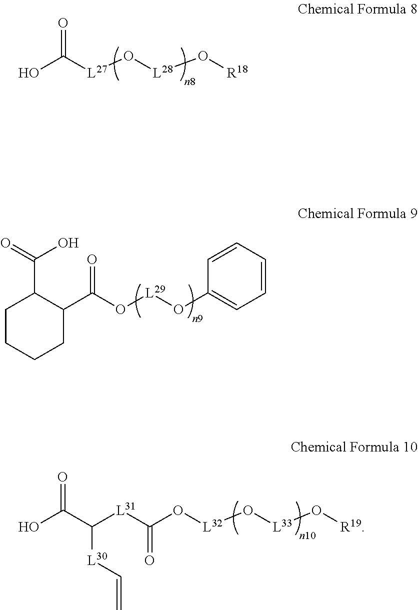

wherein, in Chemical Formulas 8 to 10,
R¹⁸ and R¹⁹ may each independently be a substituted or unsubstituted C1 to C10 alkyl group,
L²⁷ to L³³ may each independently be a substituted or unsubstituted C1 to C10 alkylene group, and
n8 to n10 may each independently be an integer of 0 to 10,

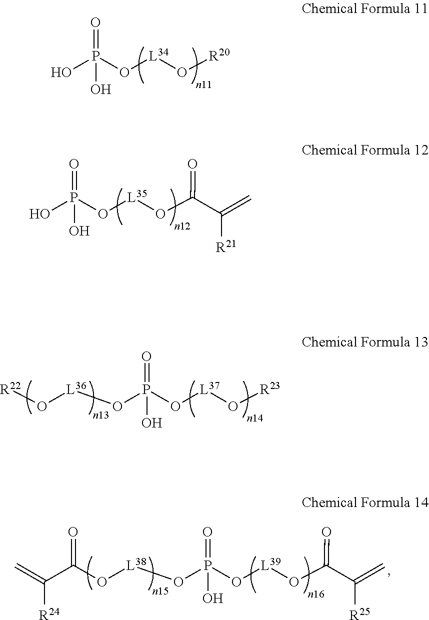

wherein, in Chemical Formulas 11 to 14,
R²⁰ to R²⁵ may each independently be hydrogen or a substituted or
unsubstituted C1 to C10 alkyl group,
L³⁴ to L³⁹ may each independently be a substituted or unsubstituted C1 to C10 alkylene group, and
n11 to n16 may each independently be an integer of 0 to 10.

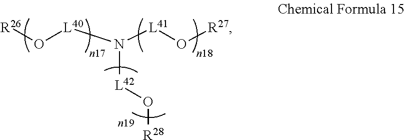

wherein, in Chemical Formula 15,
R²⁶ to R²⁸ may each independently be a substituted or unsubstituted C1 to C10 alkyl group,
L⁴⁰ to L⁴² may each independently be a substituted or unsubstituted C1 to C10 alkylene group, and
n17 to n19 may each independently be an integer of 0 to 10.

In one or more embodiments, the quantum dots may have a maximum fluorescence emission wavelength at about 500 nm to about 680 nm.

In one or more embodiments, the curable composition may be a solvent-free curable composition (e.g., the curable composition excludes a solvent).

The quantum dots may be included in an amount of about 5 wt % to about 70 wt % based on a total weight of the solvent-free curable composition.

The polymerizable compound may be included in an amount of about 30 wt % to about 95 wt % based on a total weight of the solvent-free curable composition.

In some embodiments, the curable composition may further include a polymerization initiator.

In one or more embodiments, the curable composition may further include a solvent.

In one or more embodiments, the curable composition may include about 1 wt % to about 40 wt % of the (A) quantum dots; about 1 wt % to about 20 wt % of the (B) polymerizable compound; about 10 wt % to about 30 wt % of the (C) two or more light scatterers different from each other; and about 40 wt % to about 80 wt % of the solvent based on a total weight of the curable composition.

In one or more embodiments, the curable composition may further include a polymerization inhibitor; malonic acid; 3-amino-1,2-propanediol; a silane-based coupling agent; a leveling agent; a fluorine-based surfactant; or a combination thereof.

According to one or more embodiments, a cured layer produced utilizing the curable composition is provided.

According to one or more embodiments, a display device including the cured layer is provided.

Other embodiments of the present disclosure will be embodied in the following detailed description.

The luminance of a color filter may be greatly improved by mixing and utilizing the high refractive organic-inorganic hybrid nano-sol and other materials having a different structure as a light diffusing agent.

### DETAILED DESCRIPTION

The present disclosure may be modified in many alternate forms, and thus specific embodiments will be exemplified and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, embodiments of the present disclosure are described in more detail. However, these embodiments are example, the present disclosure is not limited thereto and the present disclosure is defined by the scope of claims.

As utilized herein, when a specific definition is not otherwise provided, “alkyl group” may refer to a C1 to C20 alkyl group, “alkenyl group” may refer to a C2 to C20 alkenyl group, “cycloalkenyl group” may refer to a C3 to C20 cycloalkenyl group, “heterocycloalkenyl group” may refer to a C3 to C20 heterocycloalkenyl group, “aryl group” may refer to a C6 to C20 aryl group, “arylalkyl group” may refer to a (C6 to C20 aryl) alkyl group, “alkylene group” may refer to a C1 to C20 alkylene group, “arylene group” may refer to a C6 to C20 arylene group, “alkylarylene group” may refer to a C7 to C20 alkylarylene group, “heteroarylene group” may refer to a C3 to C20 heteroarylene group, and “alkoxylene group” may refer to a C1 to C20 alkoxylene group.

As utilized herein, when a specific definition is not otherwise provided, “substituted” may refer to replacement of at least one hydrogen by a substituent selected from among a halogen (F, Cl, Br, or I), a hydroxy group, a hydroxy group, a C1 to C20 alkoxy group, a nitro group, a cyano group, an amine group, an imino group, an azido group, an amidino group, a hydrazino group, a hydrazono group, a carbonyl group, a carbamoyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, and/or a combination thereof.

As utilized herein, when a specific definition is not otherwise provided, “hetero” may refer to inclusion of at least one heteroatom of N, O, S, or P, in the chemical formula.

As utilized herein, when a specific definition is not otherwise provided, “(meth)acrylate” may refer to both (e.g., simultaneously) “acrylate” and “methacrylate,” and “(meth)acrylic acid” refers to “acrylic acid” and/or “methacrylic acid.”

As utilized herein, when a specific definition is not otherwise provided, the term “combination” may refer to mixing or copolymerization.

In the present disclosure, when a definition is not otherwise provided, hydrogen is bonded at the position when a chemical bond is not drawn in chemical formula where supposed to be given.

In addition, in the present disclosure, when a definition is not otherwise provided, “*” refers to a linking point with the same or different atom or chemical formula.

A curable composition according to one or more embodiments may include (A) quantum dots; (B) polymerizable compound; and (C) two or more light scatterers different from each other, wherein the light scatterers may include a nano-sol.

In order to secure dispersibility of the quantum dots, a solvent may be utilized to disperse them but there may be a problem of causing marginal efficiency due to nozzle drying, deterioration of ink-jetting processibility, and input (e.g., dispersed) content (e.g., amount) limitation of the quantum dots. In order to address the problem, efforts to develop a solvent-free quantum dot ink composition utilizing no solvent have been made, but in the solvent-free quantum dot ink composition in the art, technologies of dispersing the quantum dots themselves have reached a limit as described above, and the content (e.g., amount) of the quantum dots dispersed into the composition also has reached a limit of about 20 wt % to about 25 wt %, it is not easy to improve optical characteristics to a higher level.

In order to address the issues, efforts to surface-modify the quantum dots to apply the quantum dots in a high solid content (e.g., amount) to the solvent-free composition have been made but inevitably involve an increase in viscosity of the composition, greatly deteriorating ink-jetting properties. Accordingly, in order to lower the increased viscosity to an ink-jettable level, there may be a method of reducing the solid content (e.g., amount) of the quantum dots or increasing a temperature of a head through which an ink is jetted. However, when the solid content (e.g., amount) of the quantum dots is reduced, the optical characteristics may be deteriorated, and when the head temperature is increased, ejection properties during the ink-jetting may be deteriorated, causing insufficient adhesion.

Furthermore, electrohydrodynamic (EHD) jet printing technology has recently emerged. This is a direct-printing method by ejecting/jetting an ink through an electrohydrodynamic force utilizing an electric field. Compared with the suitable inkjet printing method in the art, it has advantages of realizing nanoscale high-resolution characteristics and having a fast printing speed, an application range of one or more suitable inks, etc. Therefore, it may manufacture micro- or nano-sized structure and patterns with one or more suitable shapes and sizes, thus drawing attention as next generation printing technology.

One or more embodiments of the present disclosure relate to a high-viscosity quantum dot-containing ink composition, which is sufficiently applicable to the inkjet printing, etc. as well as the EHD jet printing to improve luminance.

Regarding a refractive index, which is important characteristics of an optical material, organic materials has a limited selection range, compared with inorganic materials. Scattering intensity depends on a relative size of a particle diameter to a wavelength of light and a refractive index ratio of a particle and a substrate, and in order to obtain a transparent organic-inorganic hybrid sol material in a visible wavelength region, nano-sized particles should be dispersed without aggregation. In the related art, because improvement of the refractive index or the transmittance but not improvement of luminance are achieved by utilizing an organic-inorganic hybrid sol material, in order to improve the luminance, inorganic particles dispersion instead of the organic-inorganic hybrid sol is tried, which may improve dispersibility but still have a limit of improving the refractive index or the transmittance. The present disclosure has confirmed that when a solvent-free type or kind curable composition is prepared by utilizing a nano-sol having a refractive index of greater than or equal to about 1.45 (specifically, an organic-inorganic hybrid nano-sol) and mixing the nano sol with a light scatterer with a different structure therefrom to prepare a mixture as a light scatterer and then, mixing the light scatterer with the quantum dots and a polymerizable monomer to control a solvent-free type or kind curable composition, satisfactory luminance improvement effects may be achieved by optimizing the improvement of the refractive index and the transmittance as well as improving dispersibility of the organic-inorganic hybrid nano-sol.

Hereinafter, each component is described in more detail.

### (C) Light Scatterers

The light scatterers reflect light that is not (e.g., initially) absorbed by the quantum dots, which will be described later, and enable the quantum dots to absorb the reflected light again. For example, the light scatterers may increase an amount of light absorbed by the quantum dots and increase light conversion efficiency of the curable composition.

The curable composition according to one or more embodiments necessarily includes two or more light scatterers differing from each other to improve a refractive index and transmittance (increase light conversion efficiency) through dispersibility improvement of the nano-sol, ultimately achieving luminance at a high level. For example, the curable composition according to one or more embodiments may include a nano-sol and a compound with a different structure from that of the nano-sol as light scatterers.

For example, in one or more embodiments, the nano-sol may have a refractive index of greater than or equal to about 1.45 and a solution transmittance of greater than or equal to about 60% (e.g., in a visible wavelength region). When the refractive index and solution transmittance of the nano-sol are within the above ranges, it is effective in improving the refractive index and transmittance, and as a result, the luminance enhancement effect may be achieved more easily.

For example, in one or more embodiments, the nano-sol may include an organic-inorganic hybrid sol. As described above, in the art, inorganic particle dispersions are utilized to improve dispersibility, resulting in losses in terms of refractive index and transmittance. However, according to one or more embodiments of the present disclosure, the refractive index and transmittance may be increased by utilizing the organic-inorganic hybrid nano-sol, and the limitation of luminance improvement due to low dispersibility, which is a problem of the organic-inorganic hybrid nano-sol in the related art, may be solved by utilizing a mixture of the organic-inorganic hybrid nano-sol and a compound having a different structure as light scatterers, and further controlling the entire composition to be a solvent-free composition

For example, in one or more embodiments, the organic-inorganic hybrid sol may include inorganic particles. The inorganic particles may include titanium, zirconium, silicon, aluminum, tin, cerium, magnesium, zinc, or a combination thereof, but embodiments of the present disclosure are not necessarily limited thereto.

For example, in one or more embodiments, the inorganic particles may be included in an amount of about 50 wt % to about 80 wt % based on a total amount of the organic-inorganic hybrid sol. When the inorganic particles are included in the above range based on a total amount of the organic-inorganic hybrid sol, an average particle diameter (D50) of the inorganic particles may be easily controlled or selected to be less than or equal to about 20 nm, for example less than or equal to about 15 nm, for example less than or equal to about 10 nm, for example about 1 nm to about 20 nm, for example about 1 nm to about 15 nm, or for example about 1 nm to about 10 nm. When the average particle diameter (D50) of the inorganic particles is controlled or selected within the above range, small-sized inorganic nanoparticles do not easily aggregate and organic-inorganic hybrid sol may be well formed. A commonly utilized light scatterers such as titanium dioxide may have an average particle diameter (D50) of about 150 nm to about 250 nm, specifically about 180 nm to about 230 nm. However, according to one or more embodiments, the organic-inorganic hybrid sol also serves as a light scatterer and thus it may be desirable that the average particle diameter (D50) of the inorganic particles constituting the organic-inorganic hybrid sol is controlled or selected within the above range.

A dispersion solvent utilized in preparing the organic-inorganic hybrid sol may include organic solvents such as pyridine, toluene, tetrahydrofuran, chloroform, dichloromethane, pentane, hexane, heptane, cyclohexane, diethyl ether, trichloroethylene, acetone, or methylethyl ketone, or a combination thereof, but embodiments of the present disclosure are not necessarily limited thereto.

Other compounds having a different structure from the nano-sol, specifically, the organic-inorganic hybrid nano-sol, may also be utilized as the light scatterers together with the nano-sol.

For example, in one or more embodiments, other compounds having a different structure from the nano-sol may include barium sulfate (BaSO₄), calcium carbonate (CaCO₃), titanium dioxide (TiO₂), zirconia (ZrO₂), or a combination thereof, but embodiments of the present disclosure are not limited thereto.

The light scatterers in the curable composition according to one or more embodiments may include the nano-sol and barium sulfate, calcium carbonate, titanium dioxide, zirconia, or a combination thereof, wherein when the nano-sol is referred to as first light scatterers, and the barium sulfate, calcium carbonate, titanium dioxide, zirconia, or a combination thereof is referred to as second light scatterers, the first light scatterers may be included in a weight equal to or greater than that of the second light-scattering material. For example, in one or more embodiments, the first light scatterers may be included in a weight of about 1 to about 5 times, for example, about 2 to about 4 times, the weight of the second light scatterers. When the mixed weight ratio between the first light scatterers and the second light scatterers is controlled or selected within the above range, the luminance improvement effect may be maximized or increased.

For example, in one or more embodiments, the light scatterers (first light scatterers, second light scatterers) may be present in an amount of about 10 wt % to about 30 wt %, for example about 12 wt % to about 25 wt %, for example about 10 wt % to about 20 wt %, or for example about 12 wt % to about 20 wt %, based on a total amount (100 wt %) of the curable composition (solvent-free curable composition). When a content (e.g., amount) of the light scatterers is within the above range, luminance of the curable composition may be greatly improved and sedimentation stability of the quantum dots may be improved.

For example, the curable composition according to one or more embodiments may be a solvent-free curable composition or a solvent type or kind curable composition including a solvent.

### (B) Polymerizable Compound

The curable composition according to one or more embodiments may include a polymerizable compound, and the polymerizable compound may have a carbon-carbon double bond at terminal ends thereof.

The polymerizable compound having the carbon-carbon double bond at the terminal ends may be included in an amount of about 30 wt % to about 95 wt %, for example about 40 wt % to about 90 wt %, based on a total amount of the solvent-free curable composition. When the polymerizable compound having the carbon-carbon double bond at the terminal ends is included within the ranges, a solvent-free curable composition having a viscosity that enables ink-jetting may be prepared and the quantum dots in the prepared solvent-free curable composition may have improved dispersibility, thereby improving optical characteristics.

For example, in one or more embodiments, the polymerizable compound having the carbon-carbon double bond at the terminal ends may have a molecular weight of about 170 g/mol to about 1,000 g/mol. When the polymerizable compound having the carbon-carbon double bond at the terminal ends has a molecular weight within the range, it may be advantageous for ink-jetting because it does not increase a viscosity of the composition without hindering the optical characteristics of the quantum dots.

For example, in one or more embodiments, the polymerizable compound having the carbon-carbon double bond at the terminal ends may be represented by Chemical Formula 1, but embodiments of the present disclosure are not necessarily limited thereto.

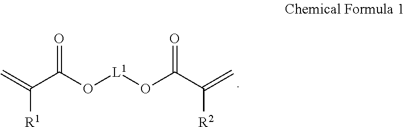

In Chemical Formula 1,
R¹ and R² may each independently be hydrogen or a methyl group,
L¹ may be a substituted or unsubstituted C1 to C30 alkylene group or *-L^{a}-O-L^{b}-* (L^{a} and L^{b} may each independently be a substituted or unsubstituted C1 to C20 alkylene group).

For example, in one or more embodiments, the polymerizable compound having a carbon-carbon double bond at the terminal ends may be represented by any one of Chemical Formulas 1-1 to 1-3, but embodiments of the present disclosure are not necessarily limited thereto.

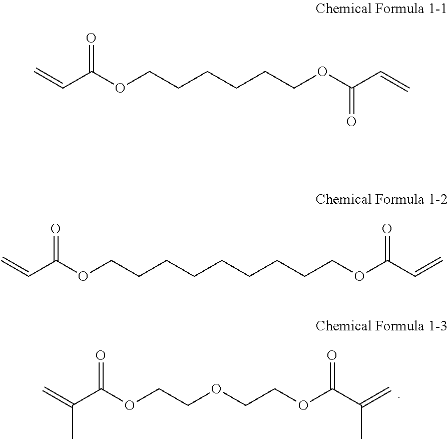

For example, in one or more embodiments, the polymerizable compound having a carbon-carbon double bond at the terminal ends may further include ethylene glycoldiacrylate, triethylene glycoldiacrylate, 1,4-butanedioldiacrylate, 1,6-hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, dipentaerythritolhexaacrylate, bisphenol A diacrylate, trimethylolpropanetriacrylate, novolac epoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof, in addition to the compounds represented by Chemical Formulas 1-1 to 1-3.

In some embodiments, together with the polymerizable compound having the carbon-carbon double bond at the terminal ends, a generally-utilized monomer of a thermosetting or photocurable composition may be further included. For example, the monomer may further include an oxetane-based compound such as bis [1-ethyl (3-oxetanyl)]methyl ether, and/or the like.

In some embodiments, when the curable composition is a solvent type or kind curable composition including a solvent, the polymerizable compound may be included in an amount of about 1 wt % to about 20 wt %, about 1 wt % to about 15 wt %, for example, or about 5 wt % to about 15 wt %. When the polymerizable compound is included within the above range, optical characteristics of the quantum dots may be improved.

### (A) Quantum Dots

The quantum dots in the curable composition according to one or more embodiments may be surface-modified quantum dots with a ligand having a polar group, for example, a ligand having high affinity with the polymerizable compound. In the case (e.g., embodiments) of the surface-modified quantum dots as described above, it may be very easy to prepare a high-concentration or highly-concentrated quantum dot dispersion (improvement of the dispersibility of the quantum dots in a polymerizable compound), which may have a great effect on improving light efficiency, especially in the desirable realization of a solvent-free curable composition.

For example, in one or more embodiments, the ligand having the polar group may have a structure having high affinity with the chemical structure of the polymerizable compound.

For example, in some embodiments, the ligand having the polar group may be any one or a combination of compounds represented by Chemical Formulas 2 to 15, but embodiments of the present disclosure are not necessarily limited thereto.

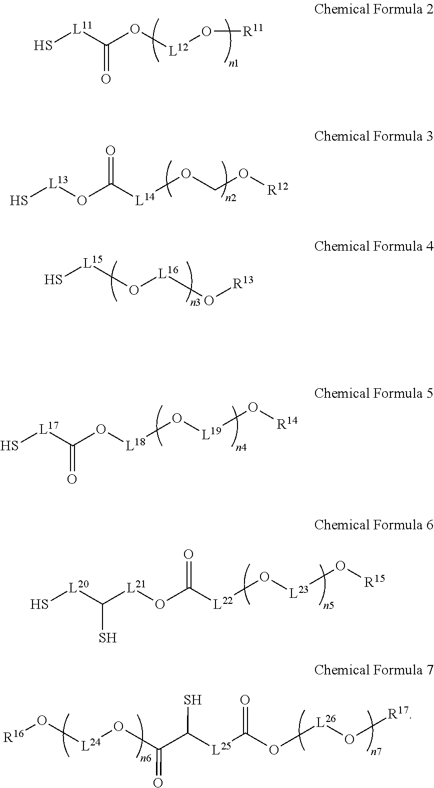

In Chemical Formulas 2 to 7,
R¹¹ to R¹⁷ may each independently be a substituted or unsubstituted C1 to C10 alkyl group or a substituted or unsubstituted C6 to C20 aryl group,
L¹¹ to L²⁶ may each independently be a substituted or unsubstituted C1 to C10 alkylene group, and
n1 to n7 may each independently be an integer of 0 to 10.

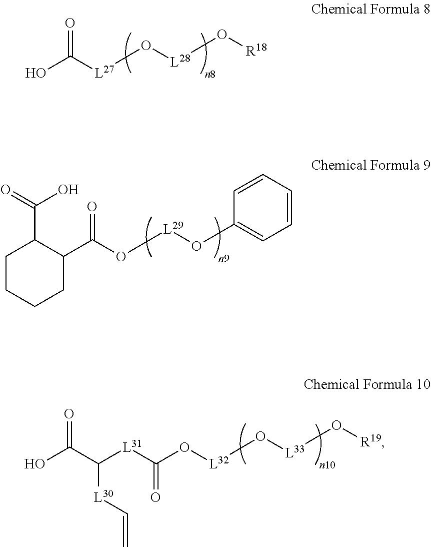

wherein, in Chemical Formulas 8 to 10,
R¹⁸ and R¹⁹ may each independently be a substituted or unsubstituted C1 to C10 alkyl group,
L²⁷ to L³³ may each independently be a substituted or unsubstituted C1 to C10 alkylene group, and
n8 to n10 may each independently be an integer of 0 to 10.

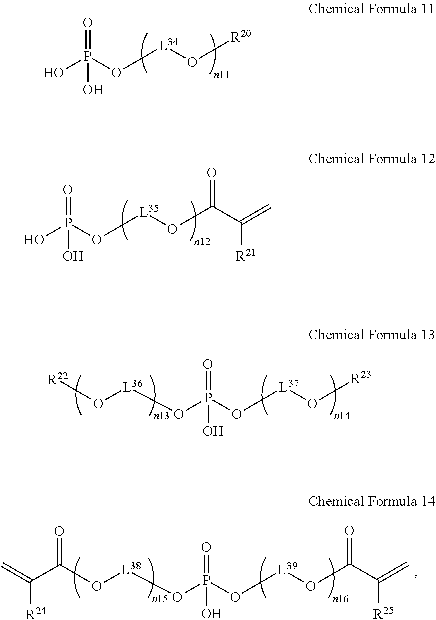

wherein, in Chemical Formulas 11 to 14,
R²⁰ to R²⁵ may each independently be hydrogen or a substituted or unsubstituted C1 to C10 alkyl group,
L³⁴ to L³⁹ may each independently be a substituted or unsubstituted C1 to C10 alkylene group, and
n11 to n16 may each independently be an integer of 0 to 10.

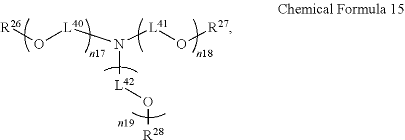

wherein, in Chemical Formula 15,
R²⁶ to R²⁸ may each independently be a substituted or unsubstituted C1 to C10 alkyl group,
L⁴⁰ to L⁴² may each independently be a substituted or unsubstituted C1 to C10 alkylene group, and
n17 to n19 may each independently be an integer of 0 to 10.

For example, in one or more embodiments, the compounds represented by Chemical Formulas 2 to 15 may be represented by any one of compounds represented by Chemical Formulas A to Q, but embodiments of the present disclosure are not necessarily limited thereto.

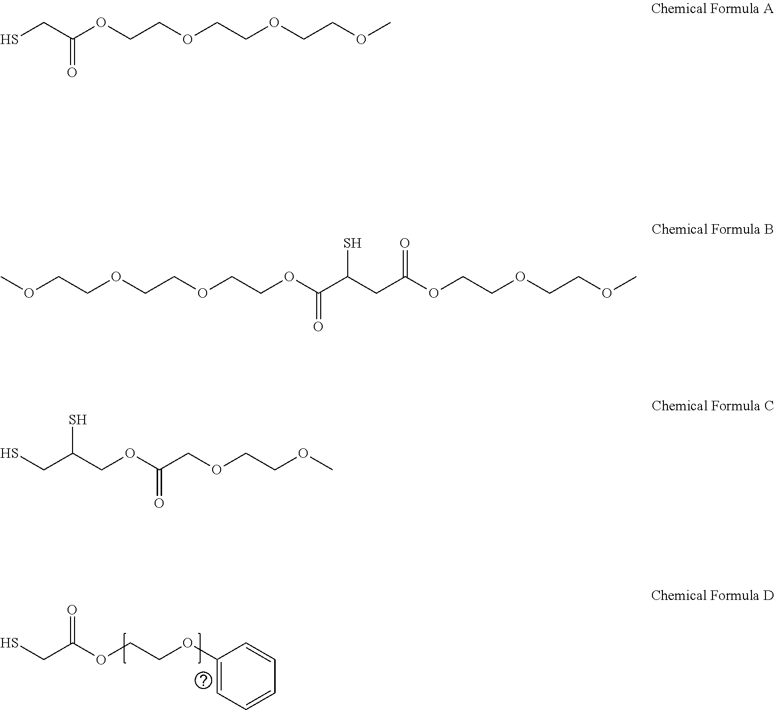

In Chemical Formula D, m1 is an integer of 0 to 10.

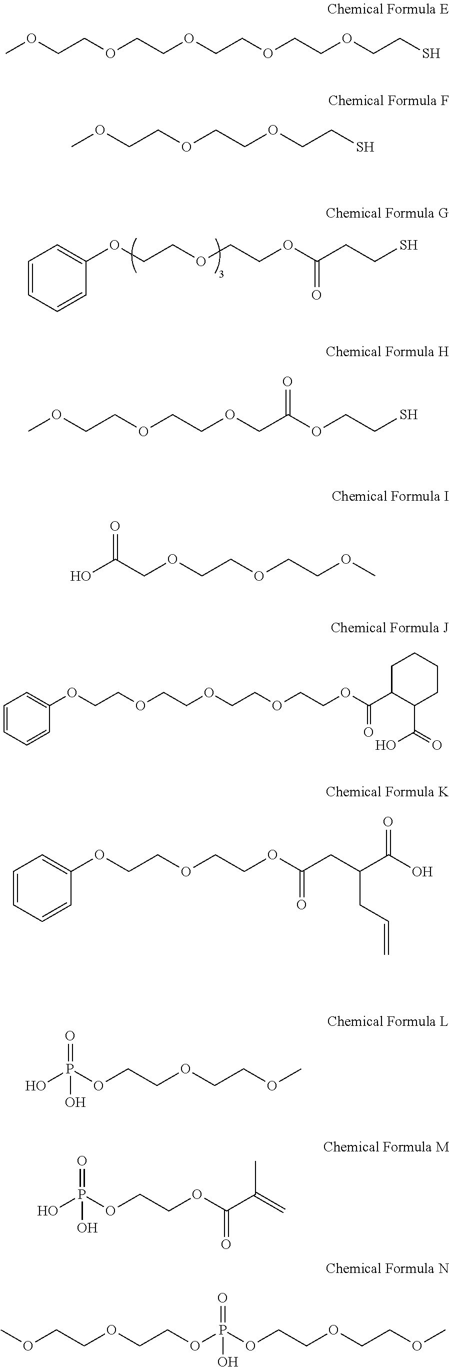

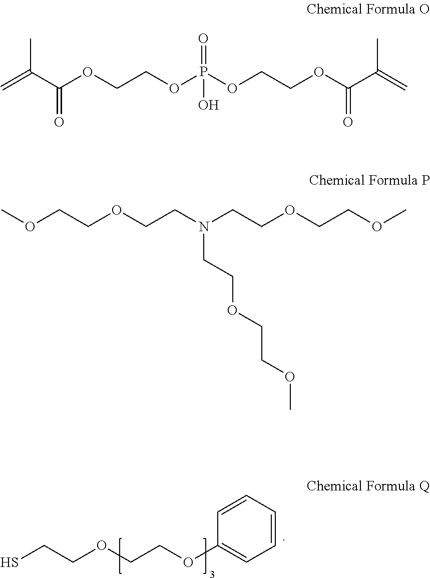

When utilizing the ligand, the surface modification of the quantum dots is easier, and when the quantum dots surface-modified with the ligand are added to the aforementioned polymerizable compound and stirred, a very transparent dispersion may be obtained, which is a criterion and indicator for confirming that the surface modification of the quantum dots is very good or suitable.

For example, when the curable composition according to one or more embodiments is a solvent-free curable composition, an amount of the quantum dots may be about 5 wt % to about 70 wt %, for example about 10 wt % to about 60 wt %, for example about 20 wt % to about 60 wt %, or for example about 30 wt % to about 50 wt %. When the quantum dots are included within the range, high light retention and light efficiency may be achieved even after curing.

For example, when the curable composition according to one or more embodiments is a solvent type or kind curable composition including a solvent, the quantum dots may be included in an amount of about 1 wt % to about 40 wt %, for example about 3 wt % to about 30 wt %, based on a total amount of the curable composition. When the quantum dots are included within the above range, the light conversion rate is improved and pattern characteristics and development characteristics are not impaired, so that excellent or suitable processibility may be obtained.

For example, in one or more embodiments, the quantum dots absorb light in a wavelength region of about 360 nm to about 780 nm, for example about 400 nm to about 780 nm and emits fluorescence in a wavelength region of about 500 nm to about 700 nm, for example about 500 nm to about 580 nm, or emits fluorescence in a wavelength region of about 600 nm to about 680 nm. For example, in one or more embodiments, the quantum dots may have a maximum fluorescence emission wavelength (fluorescence λₑₘ) at about 500 nm to about 680 nm.

The quantum dots may each independently have a full width at half maximum (FWHM) of about 20 nm to about 100 nm, for example about 20 nm to about 50 nm. When the quantum dots have a full width at half maximum (FWHM) of the above ranges, color reproducibility may be increased when utilized as a color material in a color filter due to high color purity.

In one or more embodiments, the quantum dots may each independently be an organic material, an inorganic material, or a hybrid (mixture) of an organic material and an inorganic material.

In one or more embodiments, the quantum dots may each independently be composed of a core and a shell around (e.g., surrounding) the core, and the core and the shell may each independently have a structure of a core, core/shell, core/first shell/second shell, alloy, alloy/shell, and/or the like, which is composed of Group II-IV, Group III-V, and/or the like, but embodiments of the present disclosure are not limited thereto.

For example, in one or more embodiments, the core may include at least at least one material selected from among CdS, CdSe, CdTe, ZnS, ZnSe, ZnTe, HgS, HgSe, HgTe, GaN, GaP, GaAs, InP, InAs, and an alloy thereof, but embodiments of the present disclosure are not necessarily limited thereto. The shell around (e.g., surrounding) the core may include at least at least one material selected from among CdSe, ZnSe, ZnS, ZnTe, CdTe, PbS, TiO₂, SrSe, HgSe, and an alloy thereof, but embodiments of the present disclosure are not necessarily limited thereto.

In one or more embodiments, because an interest in an environment has been recently substantially increased over the whole world, and a restriction of a toxic material also has been fortified, a cadmium-free light emitting material (InP/ZnS, InP/ZnSe/ZnS, etc.) having relatively low quantum efficiency (quantum yield) but being environmentally-friendly instead of a light emitting material having a cadmium-based core may be utilized, but embodiments of the present disclosure are not necessarily limited thereto.

In the case (e.g., embodiments) of the quantum dots of the core/shell structure, an entire size including the shell (an average particle diameter) may be about 1 nm to about 15 nm, for example, about 5 nm to about 15 nm.

For example, in some embodiments, the quantum dots may independently include red quantum dots (e.g., to emit red light), green quantum dots (e.g., to emit green light), or a combination thereof. The red quantum dots may each independently have an average particle diameter of about 10 nm to about 15 nm. The green quantum dots may each independently have an average particle diameter of about 5 nm to about 8 nm.

In one or more embodiments, for dispersion stability of the quantum dot, the curable composition according to some embodiments may further include a dispersant. The dispersant helps substantially uniform dispersibility of light conversion materials such as quantum dots in the curable composition and may include a non-ionic, anionic, or cationic dispersant. For example, in one or more embodiments, the dispersant may be polyalkylene glycol or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, alkyl amide alkylene oxide addition product, alkyl amine, and/or the like, and may be utilized alone or in a mixture of two or more. The dispersant may be utilized in an amount of about 0.1 wt % to about 100 wt %, for example about 10 wt % to about 20 wt %, based on a solid content (e.g., amount) of the light conversion material such as quantum dots.

### Polymerization Initiator

The curable composition according to one or more embodiments may further include a polymerization initiator, for example, a photopolymerization initiator, a thermal polymerization initiator, or a combination thereof.

The photopolymerization initiator may be a generally-utilized initiator for a curable resin composition, for example, an acetophenone-based compound, a benzophenone-based compound, a thioxanthone-based compound, a benzoin-based compound, a triazine-based compound, an oxime-based compound, an aminoketone-based compound, and/or the like, but embodiments of the present disclosure are not necessarily limited thereto.

Non-limiting examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio) phenyl)-2-morpholinopropan-1-one, 2-benzyl-2-dimethylamino-1-(4-morpholinophenyl)-butan-1-one, and/or the like.

Non-limiting examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino) benzophenone, 4,4′-bis(diethylamino) benzophenone, 4,4′-dimethylaminobenzophenone, 4,4′-dichlorobenzophenone, 3,3′-dimethyl-2-methoxybenzophenone, and/or the like.

Non-limiting examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and/or the like.

Non-limiting examples of the benzoin-based compound may be benzoin, benzoin methyl ether, benzoin ethyl ether, benzoin isopropyl ether, benzoin isobutyl ether, benzyldimethylketal, and/or the like.

Non-limiting examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis (trichloromethyl)-s-triazine, 2-(p-methoxyphenyl)-4,6-bis (trichloromethyl)-s-triazine, 2-(p-tolyl)-4,6-bis (trichloromethyl)-s-triazine, 2-biphenyl-4,6-bis (trichloro methyl)-s-triazine, bis (trichloromethyl)-6-styryl-s-triazine, 2-(naphtho-1-yl)-4,6-bis (trichloromethyl)-s-triazine, 2-(4-methoxynaphtho-1-yl)-4,6-bis (trichloromethyl)-s-triazine, 2-4-bis (trichloromethyl)-6-piperonyl-s-triazine, 2-4-bis (trichloromethyl)-6-(4-methoxystyryl)-s-triazine, and/or the like.

Non-limiting examples of the oxime-based compound may be O-acyloxime-based compound, 2-(O-benzoyloxime)-1-[4-(phenylthio) phenyl]-1,2-octandione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and/or the like. Non-limiting examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and/or the like.

Non-limiting examples of the aminoketone-based compound may be 2-benzyl-2-dimethylamino-1-(4-morpholinophenyl)-butanone-1, and/or the like.

In some embodiments, the photopolymerization initiator may further include a carbazole-based compound, a diketone-based compound, a sulfonium borate-based compound, a diazo-based compound, an imidazole-based compound, a biimidazole-based compound, and/or the like, besides the compounds described above.

In some embodiments, the photopolymerization initiator may be utilized with a photosensitizer capable of causing a chemical reaction by absorbing light and becoming excited and then, transferring its energy.

Non-limiting examples of the photosensitizer may be tetraethylene glycol bis-3-mercapto propionate, pentaerythritol tetrakis-3-mercapto propionate, dipentaerythritol tetrakis-3-mercapto propionate, and/or the like.

Non-limiting examples of the thermal polymerization initiator may be peroxide, for example, benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis (isobutyronitrile), t-butyl perbenzoate, and/or the like, for example, 2,2′-azobis-2-methylpropinonitrile, but embodiments of the present disclosure are not necessarily limited thereto, and any of which is well suitable in the art may be utilized.

In one or more embodiments, the polymerization initiator may be included in an amount of about 0.01 wt % to about 5 wt %, for example about 0.1 wt % to about 3 wt %, based on a total amount of the curable composition. When the polymerization initiator is included in the ranges, it may obtain excellent or suitable reliability due to sufficient curing during exposure (e.g., light exposure) or thermal curing and to prevent or reduce deterioration of transmittance due to non-reaction initiators, thereby preventing or reducing deterioration of optical characteristics of the quantum dots.

### Other Additives

For stability and dispersion improvement of the quantum dots, the curable composition according to one or more embodiments may further include a polymerization inhibitor.

The polymerization inhibitor may include a hydroquinone-based compound, a catechol-based compound, or a combination thereof, but embodiments of the present disclosure are not necessarily limited thereto. When the curable composition according to one or more embodiments further includes the hydroquinone-based compound, the catechol-based compound, or the combination thereof, room temperature cross-linking during exposure after coating the curable composition may be prevented or reduced.

For example, the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis (1,1-dimethylbutyl) hydroquinone, 2,5-bis (1,1,3,3-tetramethylbutyl) hydroquinone, catechol, t-butyl catechol, 4-methoxyphenol, pyrogallol, 2,6-di-t-butyl-4-methylphenol, 2-naphthol, tris (N-hydroxy-N-nitrosophenylaminato-O,O′) aluminum, or a combination thereof, but embodiments of the present disclosure are not necessarily limited thereto.

The hydroquinone-based compound, the catechol-based compound, or the combination thereof may be utilized in a form of dispersion. The polymerization inhibitor in a form of dispersion may be included in an amount of about 0.001 wt % to about 3 wt %, for example about 0.1 wt % to about 2 wt %, based on a total amount of the curable composition. When the polymerization inhibitor is included in the ranges, passage of time at room temperature may be solved and concurrently (e.g., simultaneously) sensitivity deterioration and surface delamination phenomenon may be prevented or reduced.

In some embodiments, the curable composition according to one or more embodiments may further include malonic acid; 3-amino-1,2-propanediol; a silane-based coupling agent; a leveling agent; a fluorine-based surfactant; or a combination thereof in order to improve heat resistance and reliability.

For example, the curable composition according to one or more embodiments may further include a silane-based coupling agent having a reactive substituent such as a vinyl group, a carboxyl group, a methacryloxy group, an isocyanate group, an epoxy group, and/or the like in order to improve close contacting properties with a substrate.

Non-limiting examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexylethyltrimethoxysilane, and/or the like, and these example silane-based coupling agent may be utilized alone or in a mixture of two or more.

The silane-based coupling agent may be utilized in an amount of about 0.01 parts by weight to about 10 parts by weight based on 100 parts by weight of the curable composition. When the silane-based coupling agent is included within the range, close contacting properties, storage capability, and/or the like are improved.

In some embodiments, the curable composition may further include a surfactant, for example a fluorine-based surfactant (e.g., a fluorine-containing surfactant) as needed in order to improve coating properties and inhibit generation of spots, that is, improve leveling performance.

In some embodiments, the fluorine-based surfactant may have a low weight average molecular weight of about 4,000 g/mol to about 10,000 g/mol, for example about 6,000 g/mol to about 10,000 g/mol. In some embodiments, the fluorine-based surfactant may have a surface tension of about 18 mN/m to about 23 mN/m (measured in a 0.1% polyethylene glycol monomethylether acetate (PGMEA) solution). When the fluorine-based surfactant has a weight average molecular weight and a surface tension within the ranges, leveling performance may be further improved, and excellent or suitable characteristics may be provided when slit coating as high-speed coating is applied because film defects may be less generated by preventing or reducing a spot generation during the high-speed coating and suppressing a vapor generation.

Non-limiting examples of the fluorine-based surfactant (e.g., fluorine-containing surfactant) may be, BM-1000®, and BM-1100® (BM Chemie Inc.); MEGAFACE F 142D®, F 172®, F 173®, and F 183® (Dainippon Ink Kagaku Kogyo Co., Ltd.); FULORAD FC-135®, FULORAD FC-170C®, FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145® (ASAHI Glass Co., Ltd.); and SH-28PA®, SH-1900, SH-193®, SZ-6032®, and SF-8428®, and/or the like (Toray Silicone Co., Ltd.); F-482, F-484, F-478, F-554, and/or the like of DIC Co., Ltd.

In some embodiments, the curable composition according to one or more embodiments may include a silicone-based surfactant in addition to the fluorine-based surfactant. Non-limiting examples of the silicone-based surfactant may be TSF400, TSF401, TSF410, TSF4440, and/or the like of Toshiba silicone Co., Ltd., but embodiments of the present disclosure are not limited thereto.

The surfactant may be included in an amount of about 0.01 parts by weight to about 5 parts by weight, for example about 0.1 parts by weight to about 2 parts by weight, based on 100 parts by weight of the curable composition. When the surfactant is included within the ranges, foreign materials are less produced in a sprayed composition.

In one or more embodiments, the curable composition may further include other additives such as an antioxidant, a stabilizer, and/or the like in a set or predetermined amount, unless properties are deteriorated.

### Solvent

In one or more embodiments, the curable composition may be a solvent type or kind curable composition that further includes a solvent.

The solvent may for example include at least one selected from among alcohols such as methanol, ethanol, and/or the like; glycol ethers such as ethylene glycol methylether, ethylene glycol ethylether, propylene glycol methylether, and/or the like; cellosolve acetates such as methyl cellosolve acetate, ethyl cellosolve acetate, diethyl cellosolve acetate, and/or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and/or the like; propylene glycol alkylether acetates such as propylene glycol monomethylether acetate, propylene glycol propylether acetate, and/or the like; ketones such as methylethylketone, cyclohexanone, 4-hydroxy-4-methyl-2-pentanone, methyl-n-propylketone, methyl-n-butylketone, methyl-n-amylketone, 2-heptanone, and/or the like; saturated aliphatic monocarboxylic acid alkyl esters such as ethyl acetate, n-butyl acetate, isobutyl acetate, and/or the like; lactate esters such as methyl lactate, ethyl lactate, and/or the like; hydroxy acetic acid alkyl esters such as methyl hydroxyacetate, ethyl hydroxyacetate, butyl hydroxyacetate, and/or the like; acetic acid alkoxyalkyl esters such as methoxymethyl acetate, methoxyethyl acetate, methoxybutyl acetate, ethoxymethyl acetate, ethoxyethyl acetate, and/or the like; 3-hydroxypropionic acid alkyl esters such as methyl 3-hydroxypropionate, ethyl 3-hydroxypropionate, and/or the like; 3-alkoxypropionic acid alkyl esters such as methyl 3-methoxypropionate, ethyl 3-methoxypropionate, ethyl 3-ethoxypropionate, methyl 3-ethoxypropionate, and/or the like; 2-hydroxypropionic acid alkyl ester such as methyl 2-hydroxypropionate, ethyl 2-hydroxypropionate, propyl 2-hydroxypropionate, and/or the like; 2-alkoxypropionic acid alkyl esters such as methyl 2-methoxypropionate, ethyl 2-methoxypropionate, ethyl 2-ethoxypropionate, methyl 2-ethoxypropionate, and/or the like; 2-hydroxy-2-methylpropionic acid alkyl esters such as methyl 2-hydroxy-2-methylpropionate, ethyl 2-hydroxy-2-methylpropionate, and/or the like; 2-alkoxy-2-methylpropionic acid alkyl esters such as methyl 2-methoxy-2-methylpropionate, ethyl 2-ethoxy-2-methylpropionate, and/or the like; esters such as 2-hydroxyethyl propionate, 2-hydroxy-2-methylethyl propionate, hydroxyethyl acetate, methyl 2-hydroxy-3-methylbutanoate, and/or the like; and ketonate esters such as ethyl pyruvate, and/or the like, or may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and/or the like, but embodiments of the present disclosure are not limited thereto.

For example, in some embodiments, the solvent may be desirably glycol ethers such as ethylene glycol monoethylether, ethylene diglycolmethylethylether, and/or the like; ethylene glycol alkylether acetates such as ethyl cellosolve acetate, and/or the like; esters such as 2-hydroxy ethyl propionate, and/or the like; carbitols such as diethylene glycol monomethylether, and/or the like; propylene glycol alkylether acetates such as propylene glycol monomethylether acetate, propylene glycol propylether acetate, and/or the like; alcohols such as ethanol, and/or the like, or a combination thereof.

For example, in some embodiments, the solvent may be a polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

In one or more embodiments, the solvent may be included in an amount of about 40 wt % to about 80 wt %, for example, about 45 wt % to about 80 wt %, based on a total amount of the curable composition. When the solvent is within the range, the solvent type or kind curable composition has appropriate or suitable viscosity and thus may have excellent or suitable coating property when coated in a large area through spin-coating and slit-coating.

one or more embodiments of the present disclosure provide a cured layer produced utilizing the aforementioned curable composition, a color filter including the cured layer, and a display device including the color filter.

One of methods of producing the cured layer may include coating the aforementioned curable composition and/or solvent type or kind curable composition on a substrate utilizing an ink-jet spraying method to form a pattern (S1); and curing the pattern (S2).

### (S1) Formation of Pattern

The curable composition may desirably be coated to be about 0.5 μm to about 20 μm on a substrate in an ink-jet spraying method. The ink-jet spraying method may form a pattern by spraying a single color per each nozzle and thus repeating the spraying as many times as the needed number of colors, but the pattern may be formed by concurrently (e.g., simultaneously) spraying the needed number of colors through each ink-jet nozzle in order to reduce processes.

### (S2) Curing

The obtained pattern is cured to obtain a pixel. Herein, the curing method may be a thermal curing or photocuring process. The thermal curing process may be performed at greater than or equal to about 100° C., for example, in a range of about 100° C. to about 300° C., or in a range of about 160° C. to about 250° C. The photocuring process may include irradiating an actinic ray such as a UV ray of about 190 nm to about 450 nm, for example about 200 nm to about 400 nm. As a light source utilized for irradiation, a low-pressure mercury lamp, a high-pressure mercury lamp, an ultra-high-pressure mercury lamp, a metal halide lamp, an argon gas laser, an i-line, KrF, ArF, I-ArF, EUV, X-ray, an electron beam, etc. may be utilized as needed.

The other method of producing the cured layer may include producing a cured layer utilizing the aforementioned curable composition or solvent type or kind curable composition by a lithographic method as follows.

### (1) Coating and Film Formation

The aforementioned curable composition may be coated to have a desired or suitable thickness, for example, a thickness in a range of about 2 μm to about 10 μm, on a substrate which undergoes a set or predetermined pretreatment, utilizing a spin or slit coating method, a roll coating method, a screen-printing method, an applicator method, and/or the like. Then, the coated substrate is heated at a temperature of about 70° C. to about 90° C. for about 1 minute to about 10 minutes to remove a solvent and to form a film.

### (2) Exposure

The resultant film may be irradiated by an actinic ray such as a UV ray of about 190 nm to about 450 nm, for example about 200 nm to about 400 nm after putting a mask with a set or predetermined shape to form a desired or suitable pattern. As a light source utilized for irradiation, a low-pressure mercury lamp, a high-pressure mercury lamp, an ultra-high-pressure mercury lamp, a metal halide lamp, an argon gas laser, an i-line, KrF, ArF, I-ArF, EUV, X-ray, an electron beam, etc. may be utilized as needed.

Exposure process may utilize, for example, a light dose of 500 mJ/cm² or less (with a 365 nm sensor) when a high-pressure mercury lamp is utilized. However, the light dose may vary depending on types (kinds) of each component of the curable composition, its combination ratio, and a dry film thickness.

### (3) Development

After the exposure process, an alkali aqueous solution may be utilized to develop the exposed film by dissolving and removing an unnecessary part except the exposed part, forming an imaged pattern. For example, when the alkali developing solution is utilized for the development, an unexposed region is dissolved, and an imaged color filter pattern is formed.

### (4) Post-treatment

The developed imaged pattern may be heated again or irradiated by an actinic ray and/or the like for curing, in order to accomplish excellent or suitable quality in terms of heat resistance, light resistance, close contacting properties, crack-resistance, chemical resistance, high strength, storage stability, and/or the like.

Hereinafter, the present disclosure will be illustrated in more detail with reference to examples. These examples, however, are not in any sense to be interpreted as limiting the scope of the present disclosure.

### Preparation of Organic-inorganic Hybrid Sol

### Preparation Example 1

A dispersant (phosphoric acid ester, BYK-111) and phenoxy benzyl acrylate (Hannong Chemicals Inc.) were stirred until they became substantially uniform, and ZrO₂ nanoparticles (60 wt %) were added thereto and then, pre-stirred for about 1 hour so that the nanoparticles were wetted in the dispersion solution. Subsequently, they were transferred to a bead mill filled with ZrO₂ balls with a diameter of 0.1 mm and dispersed for 20 hours at a substantially uniform speed, preparing an organic-inorganic hybrid sol with an average particle diameter of 10 nm based on D50 (a refractive index: 1.65, a solution transmittance: 72%).

### Preparation Example 2

An organic-inorganic hybrid sol with an average particle diameter of 10 nm based on D50 (refractive index: 1.76, a solution transmittance: 65%) was prepared in substantially the same manner as in Preparation Example 1 except that TiO₂ nanoparticles instead of the ZrO₂ nanoparticles and a bead mill filled with TiO₂ balls instead of the bead mill filled with ZrO₂ balls were utilized.

### Preparation of Surface-modified Quantum Dot Dispersion

### Preparation Example 3

After putting a magnetic bar in a 3-necked round bottom flask, a green quantum dot dispersion solution (a quantum dot solid content (e.g., amount): 23 wt %, InP/ZnSe/ZnS, Hansol Chemicals Co.) was put therein. Subsequently, a compound represented by Chemical Formula Q (ligand) was added thereto and then, stirred at 80° C. under a nitrogen atmosphere. When a reaction was completed, the resultant was cooled to room temperature (23° C.), and the quantum dot reaction solution was added to cyclohexane to catch precipitates. The precipitates were separated from the cyclohexane through centrifugation and sufficiently dried in a vacuum oven for 24 hours, obtaining surface-modified quantum dots.

The surface-modified green quantum dots were stirred in a polymerizable compound for 12 hours, obtaining surface-modified quantum dot dispersion (QD solid content (e.g., amount): 23 wt %).

### Synthesis of a Compound Represented by Chemical Formula Q

100 g of PH-4 (HanNong Chemical Inc.) was sufficiently dissolved in 300 mL of tetrahydrofuran (THF) in the 2-necked round bottom flask. At 0° C., 15.4 g of NaOH and 100 ml of water were added thereto and then, sufficiently dissolved, until a clear solution was obtained. Subsequently, a solution prepared dissolving 73 g of para-toluene sulfonic chloride in 100 mL of THF was slowly injected thereinto at 0° C. Herein, the injection proceeded for 1 hour and then, stirred at room temperature for 12 hours. When a reaction was completed, an excessive amount of methylene chloride was added thereto and then, stirred, and a NaHCO₃ saturated solution was added thereto and then, proceeded with extraction, and appropriate or suitable moisture removal. After removing a solvent, drying was performed in a dry oven for 24 hours. 50 g of the dried product was put in a two-necked round bottom flask and then, sufficiently stirred in 300 mL of ethanol. Subsequently, 27 g of thiourea was added thereto and dispersed therein and then, refluxed at 80° C. for 12 hours. Then, an aqueous solution prepared by dissolving 4.4 g of NaOH in 20 mL of water was injected thereinto and then, further stirred for 5 hours, an excessive amount of methylene chloride was added thereto and then, stirred, and a hydrochloric acid aqueous solution was added thereto and then, sequentially proceeded with extraction, titration, moisture removal, and solvent removal. Subsequently, drying was formed in a vacuum oven for 24 hours, obtaining a compound represented by Chemical Formula Q.

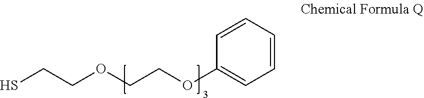

### Preparation of Curable Composition

### Examples 1 and 2 and Comparative Examples 1 to 5

Each curable composition of Examples 1 and 2 and Comparative Examples 1 to 5 was prepared to have compositions shown in Table 1 by utilizing the following components.

For example, the quantum dot dispersion was weighed and then, mixed and diluted with a polymerizable compound and then, further stirred for 5 minutes. Subsequently, a polymerization initiator was added thereto, and a light scatterer was added thereto. Then, a corresponding crude solution was stirred for 1 hour, preparing a curable composition.

### (A) Quantum Dots

Surface-modified green quantum dot dispersion prepared from Preparation Example 3

### (B) Polymerizable Compound

(B-1) A compound represented by Chemical Formula 1-1 (M200, Miwon Chemical Co.)

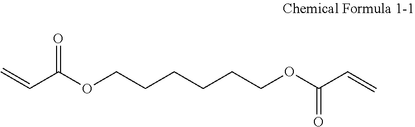 [SMILES: C=CC(=O)OCCCCCCOC(=O)C=C]

(B-2) A compound represented by Chemical Formula 1-2 (LIGHT ACRYLATE 1.9NDA, Kyoeisha Co.) (refractive index: 1.46)

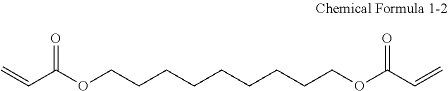 [SMILES: C=CC(=O)OCCCCCCCCCOC(=O)C=C]

(B-3) Phenoxyethyl methacrylate (refractive index: 1.52)

### (C) Light Scatterers

(C-1) Organic-inorganic hybrid sol of Preparation Example 1
(C-2) Organic-inorganic hybrid sol of Preparation Example 2
(C-3) Titanium dioxide dispersion (TiOz solid content (e.g., amount) 20 wt %, average particle diameter: 200 nm, Dito Technology Co., Ltd.)

### (D) Polymerization Initiator

TPO-L (2,4,6-trimethylbenzoyl di-phenylphosphinate, Polynetron Co.)

TABLE 1
(unit: wt %)

| | | | | Comp. | Comp. | Comp. | Comp. | Comp. |
|---|---|---|---|---|---|---|---|---|
| | | Ex. 1 | Ex. 2 | Ex. 1 | Ex. 2 | Ex. 3 | Ex. 4 | Ex. 5 |
| (A) Quantum dots | | 41 | 41 | 41 | 41 | 41 | 41 | 41 |
| (B) | (B-1) | 42 | 42 | 42 | 42 | 42 | 42 | 54 |
| Polymerizable | (B-2) | — | — | 12 | — | — | — | — |
| compound | (B-3) | — | — | — | 12 | — | — | — |
| (C) Light | (C-1) | 12 | — | — | — | 16 | — | — |
| scatterers | (C-2) | — | 12 | — | — | — | 16 | — |
| | (C-3) | 4 | 4 | 4 | 4 | — | — | 4 |

| | | | | | | | |
|---|---|---|---|---|---|---|---|
| (D) Photopolymerization | 1 | 1 | 1 | 1 | 1 | 1 | 1 |
| initiator | | | | | | | |

### Evaluation 1: Evaluation of Optical Characteristics

Each of the solvent-free curable compositions of Examples 1 and 2 and Comparative Examples 1 to 5 was coated to be 10 μm thick on a yellow photoresist (YPR) by utilizing a spin coater (830 rpm, 5 seconds, Opticoat MS-A150, Mikasa Co., Ltd.) and exposed to light with 5000 mJ (83° C., 10 seconds) by utilizing a UV exposer at 365 nm under a nitrogen atmosphere. Subsequently, 2 cm×2 cm single film specimens were loaded in an integrating sphere equipment (QE-2100, Otsuka Electronics Co., Ltd.), dried at 180° C. in a drying furnace under a nitrogen atmosphere for 30 minutes and then, measured with respect to quantum efficiency (EQE; %), and the results are shown in Table 2.

TABLE 2

| | | | Comp. | Comp. | Comp. | Comp. | Comp. |
|---|---|---|---|---|---|---|---|
| | Ex. 1 | Ex. 2 | Ex. 1 | Ex. 2 | Ex. 3 | Ex. 4 | Ex. 5 |
| Quantum efficiency (EQE) (%) | 35.9 | 36.5 | 33.6 | 34.4 | 23.5 | 25.1 | 33.6 |

Referring to Table 2, the curable composition according to one or more embodiments exhibited very excellent or suitable optical characteristics.

### Evaluation 2: Evaluation of Luminance

Each of the solvent-free curable compositions of Examples 1 and 2 and Comparative Examples 1 to 5 was coated to be 1 μm to 3 μm thick on a degreased 1 mm-thick glass substrate and dried at 90° C. on a hot plate for 2 minutes, obtaining a film. The film was exposed to light by utilizing a high-pressure mercury lamp with a main wavelength of 365 nm. Subsequently, the exposed film was dried at 180° C. in a forced convection drying furnace for 30 minutes, obtaining a sample. A pixel layer was measured with respect to luminance Y by utilizing a spectrophotometer (MCPD3000, Otsuka Electronics Co., Ltd.), and the results are shown in Table 3.

TABLE 3

| | Ex. 1 | Ex. 2 | Comp. Ex. 1 | Comp. Ex. 2 | Comp. Ex. 3 | Comp. Ex. 4 | Comp. Ex. 5 |
|---|---|---|---|---|---|---|---|
| Luminance (%) | 72.6 | 73.0 | 60.1 | 60.8 | 58.6 | 59.4 | 60.2 |

Referring to Table 3, the curable composition according to one or more embodiments exhibited very excellent or suitable effects of improving luminance characteristics.

Herein, it should be understood that terms such as “comprise(s),” “include(s),” or “have/has” are intended to designate the presence of an embodied feature, number, step, element, or a combination thereof, but it does not preclude the possibility of the presence or addition of one or more other features, number, step, element, or a combination thereof.

As utilized herein, the singular forms “a,” “an,” and “the” are intended to include the plural forms as well, unless the context clearly indicates otherwise. Further, the utilization of “may” when describing embodiments of the present disclosure may refer to “one or more embodiments of the present disclosure”. Further, as used herein, the term “and/or” includes any and all combinations of one or more of the associated listed items. The “/” utilized herein may be interpreted as “and” or as “or” depending on the situation. Expressions such as “at least one of,” “one of,” and “selected from,” when preceding a list of elements, modify the entire list of elements and do not modify the individual elements of the list. For example, “at least one of a, b, or c”, “at least one of a, b, and/or c”, “at least one selected from a, b, and c”, “at least one selected from among a to c”, etc. may indicate only a, only b, only c, both (e.g., simultaneously) a and b, both (e.g., simultaneously) a and c, both (e.g., simultaneously) b and c, all of a, b, and c, or variations thereof.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the terms “substantially,” “about,” and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when the electrode active material particles are spherical, “size” or “diameter” indicates a particle diameter or an average particle diameter, and when the particles are non-spherical, the “size” or “diameter” indicates a major axis length or an average major axis length. That is, when particles are spherical, “diameter” indicates a particle diameter, and when the particles are non-spherical, the “diameter” indicates a major axis length. The size or diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

A display device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

While the present disclosure has been described in connection with what is presently considered to be practical example embodiments, it is to be understood that the present disclosure is not limited to the disclosed embodiments, but, on the contrary, is intended to cover one or more suitable modifications and equivalent arrangements included within the spirit and scope of the appended claims and equivalents thereof. Therefore, the aforementioned embodiments should be understood to be examples but not limiting the present disclosure in any way.

What is claimed is:

1. A curable composition, comprising
quantum dots;
a polymerizable compound; and
two or more light scatterers different from each other
wherein the light scatterers comprise a nano-sol.

2. The curable composition of claim 1, wherein
the nano-sol has a refractive index of greater than or equal to about 1.45 and a solution transmittance of greater than or equal to about 60%.

3. The curable composition of claim 1, wherein
the nano-sol comprises an organic-inorganic hybrid sol.

4. The curable composition of claim 3, wherein
the organic-inorganic hybrid sol comprises inorganic particles comprising titanium, zirconium, silicon, aluminum, tin, cerium, magnesium, zinc, or a combination thereof.

5. The curable composition of claim 4, wherein
the inorganic particles are comprised in an amount of about 50 wt % to about 80 wt % based on a total amount of the organic-inorganic hybrid sol.

6. The curable composition of claim 4, wherein
the inorganic particles have an average particle diameter (D50) of less than or equal to about 20 nm.

7. The curable composition of claim 1, wherein
the light scatterers further comprise barium sulfate, calcium carbonate, titanium dioxide, zirconia, or a combination thereof.

8. The curable composition of claim 7, wherein
the nano-sol is comprised in a weight equal to or greater than that of the barium sulfate, calcium carbonate, titanium dioxide, zirconia, or a combination thereof in the curable composition.

9. The curable composition of claim 7, wherein
the nano-sol is comprised in a weight of about 1 to about 5 times a weight of the barium sulfate, calcium carbonate, titanium dioxide, zirconia, or a combination thereof.

10. The curable composition of claim 1, wherein
the polymerizable compound comprises a compound represented by Chemical Formula 1: 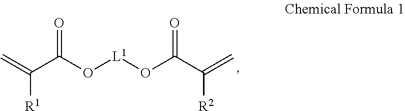
wherein, in Chemical Formula 1,
R¹ and R² are each independently hydrogen or a methyl group, and
L¹ is a substituted or unsubstituted C1 to C30 alkylene group or *-L^{a}-O-L^{b}-* (wherein L^{a} and L^{b} are each independently a substituted or unsubstituted C1 to C20 alkylene group).

11. The curable composition of claim 10, wherein
the compound represented by Chemical Formula 1 is represented by any one of Chemical Formulas 1-1 to 1-3:

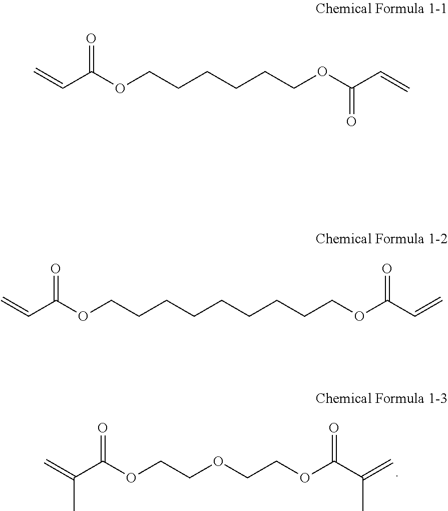

12. The curable composition of claim 1, wherein
the quantum dots are surface-modified quantum dots surface modified with any one of compounds represented by Chemical Formulas 2 to 15 or a combination thereof: 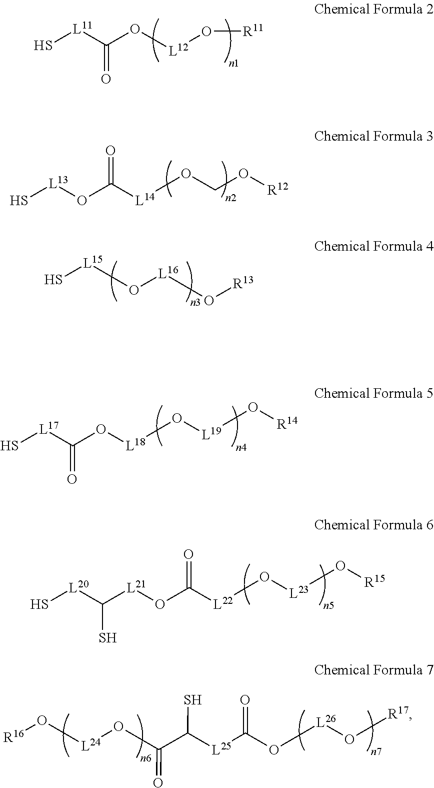
wherein, in Chemical Formulas 2 to 7,
R¹¹ to R¹⁷ are each independently a substituted or unsubstituted C1 to C10 alkyl group or a substituted or unsubstituted C6 to C20 aryl group,
L¹¹ to L²⁶ are each independently a substituted or unsubstituted C1 to C10 alkylene group, and
n1 to n7 are each independently an integer of 0 to 10, 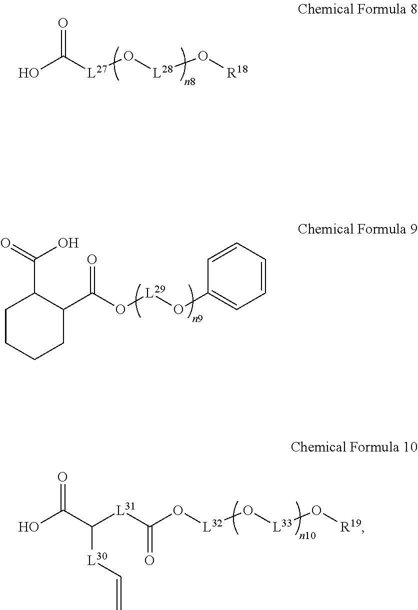
wherein, in Chemical Formulas 8 to 10,
R¹⁸ and R¹⁹ are each independently a substituted or unsubstituted C1 to C10 alkyl group,
L²⁷ to L³³ are each independently a substituted or unsubstituted C1 to C10 alkylene group, and
n8 to n10 are each independently an integer of 0 to 10, 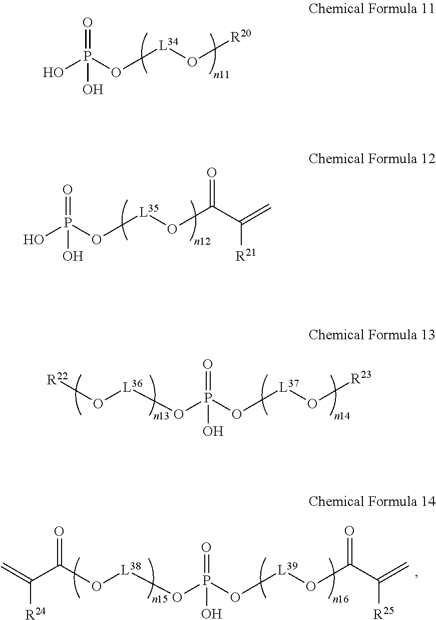
wherein, in Chemical Formulas 11 to 14,
R²⁰ to R²⁵ are each independently hydrogen or a substituted or unsubstituted C1 to C10 alkyl group,
L³⁴ to L³⁹ are each independently a substituted or unsubstituted C1 to C10 alkylene group, and
n11 to n16 are each independently an integer of 0 to 10, 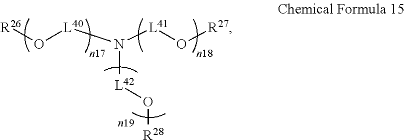
and
wherein, in Chemical Formula 15,
R²⁶ to R²⁸ are each independently a substituted or unsubstituted C1 to C10 alkyl group,
L⁴⁰ to L⁴² are each independently a substituted or unsubstituted C1 to C10 alkylene group, and
n17 to n19 are each independently an integer of 0 to 10.

13. The curable composition of claim 1, wherein
the quantum dots have a maximum fluorescence emission wavelength at about 500 nm to about 680 nm.

14. The curable composition of claim 1, wherein
the curable composition is a solvent-free curable composition.

15. The curable composition of claim 14, wherein
the quantum dots are comprised in an amount of about 5 wt % to about 70 wt % based on a total weight of the solvent-free curable composition.

16. The curable composition of claim 14, wherein
the polymerizable compound is comprised in an amount of about 30 wt % to about 95 wt % based on a total weight of the solvent-free curable composition.

17. The curable composition of claim 1, wherein
the curable composition further comprises a polymerization initiator.

18. The curable composition of claim 1, wherein
the curable composition further comprises a solvent.

19. The curable composition of claim 18, wherein
the curable composition comprises:
about 1 wt % to about 40 wt % of the quantum dots;
about 1 wt % to about 20 wt % of the polymerizable compound;
about 10 wt % to about 30 wt % of the two or more light scatterers different from each other; and
about 40 wt % to about 80 wt % of the solvent,
based on a total weight of the curable composition.

20. The curable composition of claim 1, wherein
the curable composition further comprises a polymerization inhibitor; malonic acid; 3-amino-1,2-propanediol; a silane-based coupling agent; a leveling agent; a fluorine-based surfactant; or a combination thereof.

21. A cured layer produced utilizing the curable composition of claim 1.

22. A color filter comprising the cured layer of claim 21.

23. A display device comprising the color filter of claim 22.

24. A method of producing a cured layer, the method comprising applying the curable composition of claim 1 on a substrate and curing the applied curable composition.
